(19) United States
(12) Patent Application Publication
(10) Pub. No.: US 2015/0294957 A1
(43) Pub. Date: Oct. 15, 2015

(54) CHIP PACKAGING STRUCTURE

(71) Applicant: ChipMOS Technologies Inc., Hsinchu (TW)

(72) Inventor: Chi-Jin SHIH, Hsinchu (TW)

(21) Appl. No.: 14/663,811

(22) Filed: Mar. 20, 2015

(30) Foreign Application Priority Data
Apr. 10, 2014 (TW) 103113160

(51) Int. Cl. H01L 25/065

(52) U.S. Cl. CPC H01L 25/0657; H01L 2225/06527

(57) ABSTRACT

A chip packaging structure includes an encapsulating material, plurality of first leads, plurality of second leads, a first chip, a second chip and an adhesion layer. The encapsulating material has a top package surface and a corresponding bottom package surface. Each first lead has a first inner lead portion and a first outer lead portion. The first chip is located on the first inner lead portion and electrically coupled to the first leads. Each second lead has a second inner lead portion and a second outer lead portion. The second chip is located on the second inner lead portion and electrically coupled to the second leads. The adhesion layer is located between the first leads and second leads so that the first leads and second leads are connected to each other.

### CROSS REFERENCE TO RELATED APPLICATION

This application claims priority to Taiwan Patent Document No. 103113160, filed on Apr. 10, 2014 with the Taiwan Patent Office, which is incorporated by reference in its entirety.

### BACKGROUND OF THE INVENTION

1. Field of the Invention

The present invention relates to a chip packaging structure, more particularly, to a chip packaging structure of lead frame packaging.

2. Description of the Prior Art

As the consumer market changes, consumer demands for lightness, thinness and small form factor for products are increasingly strong, especially for the electronic products, in which the capability to provide more functions, greater data capacity and faster processing speed within a limited volume is needed. However, in the semiconductor technology the integration density of chips are continuously upgraded due to the development of nanotechnology. Accordingly, higher density and pin counts are also requested for the semiconductor chip packaging. Therefore, the stacking and integration of the chips inside a package or the stacking of the packages are widely applied in many electronic devices. For example, in the dynamic random access memory (DRAM), flash memory, solid state drives (SSD), etc., can all find the application of chip stacking technology or package stacking technology (Package on Package, PoP) so as to increase the memory capacity. Furthermore, the package stacking technology can also be applied to the stacking of a memory chip package and a logic chip package.

Thus, either the chip stacking package or the stacking of packages is recently an important topic of research in this field.

### SUMMARY OF THE INVENTION

One aspect of the present invention is to provide a chip packaging structure, in which two leadframe type semifinished products of Lead On Chip (LOC)/Chip On Lead (COL) are stacked together to form a package unit which are favorable for the stacking of the packages.

Another aspect of the present invention is to provide a chip packaging structure, which uses the attachment of the lead frames to combine two identical or different chips in a package unit so as to benefit the stacking of the packages.

Yet another aspect of the present invention is to provide a chip packaging structure, in which two lead frames are bonded to form a package unit with external contact points on both the top and bottom surfaces of the package unit so as to benefit the stacking of multiple packages.

An object of the present invention is to provide a chip packaging structure comprising an encapsulating material, a plurality of first leads, a first chip, a plurality of second leads, a second chip, and an adhesion layer. The encapsulating material has a top package surface and a bottom package surface opposite to the top package surface. Each of the first leads has a first inner lead and a first outer lead. The first leads are disposed in the encapsulating material. A first surface of the first outer leads is exposed on the top package surface. The first chip is disposed in the encapsulating material. The first chip is located on the first inner leads and electrically coupled to the first leads. Each of the second leads has a second inner lead and a second outer lead. The second leads are disposed in the encapsulating material. A second surface of the second outer leads is exposed on the bottom package surface. The second chip is disposed in the encapsulating material. The second chip is located on the second inner leads and electrically coupled to the second leads. The adhesion layer is disposed in the encapsulating material and located between the first leads and the second leads so that the first leads and the second leads are connected to each other.

Another object of the present invention is to provide an electronic device comprising a chip packaging structure and a circuit board. The chip packaging structure comprises an encapsulating material, a plurality of first leads, a first chip, a plurality of second leads, a second chip, and an adhesion layer. The encapsulating material has a top package surface and a bottom package surface opposite to the top package surface. Each of the first leads has a first inner lead and a first outer lead. The first leads are disposed in the encapsulating material. A first surface of the first outer leads is exposed on the top package surface. The first chip is disposed in the encapsulating material. The first chip is located on the first inner leads and electrically coupled to the first leads. Each of the second leads has a second inner lead and a second outer lead. The second leads are disposed in the encapsulating material. A second surface of the second outer leads is exposed on the bottom package surface. The second chip is disposed in the encapsulating material. The second chip is located on the second inner leads and electrically coupled to the second leads. The adhesion layer is disposed in the encapsulating material and located between the first leads and the second leads so that the first leads and the second leads are connected to each other. The chip packaging structure is disposed on the circuit board and electrically coupled to the circuit board through the second surface of the second outer leads.

For the chip packaging structure of the present invention, two leadframe type semifinished products of Lead On Chip (LOC)/Chip On Lead (COL) are stacked together to form a package unit which are favorable for the stacking of the packages. Moreover, in the invention the thickness of the inner leads is thinned to form a space for accommodating the chip so that the chip packaging structure can also be thinned.

The chip packaging structure of the present invention uses the attachment of the lead frames to combine two identical or different chips in a package unit so as to benefit the stacking of the packages, wherein by using the electrically conductive adhesive and/or the electrically non-conductive adhesive to bond the outer leads of the two lead frames, the outer leads can then be selectively electrically coupled to or electrically isolated from each other for some particular pins according to the requirements so that the circuit design and pin assignment of the chip packaging structure can be more flexible.

For the chip packaging structure of the present invention, two lead frames are bonded to form a package unit with external contact points on both the top and bottom surfaces of the package unit so as to benefit the stacking of multiple packages. Moreover, the stacked package structure can always have the external contact points on both the uppermost surface and the bottommost surface for additional connection to other devices such that the circuit design and pin assignment of the chip packaging structure are more flexible.

### BRIEF DESCRIPTION OF THE APPENDED DRAWINGS

FIG. 1 is a schematic cross sectional view illustrating a chip packaging structure according to an embodiment of the present invention.

FIG. 2 is a schematic cross sectional view illustrating a chip packaging structure according to another embodiment of the present invention.

FIG. 3 is a partially enlarged perspective view illustrating region A shown in FIG. 1 according to an embodiment of the present invention.

FIG. 4 is a partially enlarged perspective view illustrating region A shown in FIG. 1 according to another embodiment of the present invention.

FIG. 5 is a schematic cross sectional view illustrating the chip packaging structures that stack on each other according to an embodiment of the present invention.

FIG. 6 is a schematic cross sectional view illustrating the chip packaging structures that stack on each other and are disposed on a circuit board according to an embodiment of the present invention.

To facilitate understanding, identical reference numerals have been used, where it is possible to designate identical elements that are common to the figures.

### DETAILED DESCRIPTION OF THE INVENTION

In order to allow the advantages, spirit and features of the present invention to be more easily and clearly understood, the embodiments and appended drawings thereof are discussed in the following. However, the present invention is not limited to the embodiments and appended drawings.

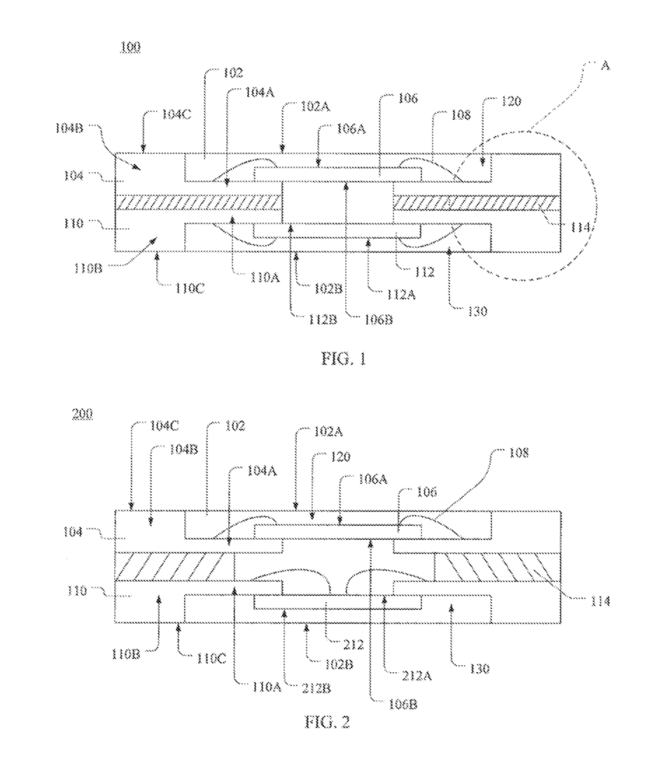

Please refer to FIG. 1, which is a schematic cross sectional view illustrating a chip packaging structure according to an embodiment of the present invention. The chip packaging structure 100 of the present invention uses lead frames as the packaging carrier that is constituted by two lead frames arranged in top and bottom fashion, as shown in FIG. 1. The top lead frame has a plurality of first leads 104. Each of the first leads 104 has a first inner lead 104A and a first outer lead 104B. In some embodiments of the present invention, the thickness of the first inner leads 104A is smaller than the thickness of the first outer leads 104B so that a first accommodation space 120 is formed in the region of the first inner leads 104A. A first chip 106 is disposed in the first accommodation space 120 and located on the first inner leads 104A. The first chip 106 has a first active surface 106A and a first rear surface 106B. The first chip 106 is attached to the first inner leads 104A with the first rear surface 106B, preferably by an insulating adhesive paste or an insulating tape (not shown). The structure formed by the first chip 106 being mounted on the first inner leads 104A with the first rear surface 106B is referred to as the Chip On Lead (COL) structure in the field of the present invention. A plurality of contact points (not shown) are disposed on the first active surface 106A of the first chip 106 and are electrically coupled to the first leads 104 by bonding wires 108 respectively, where the connection positions are preferably at the first inner leads 104A.

The structure of the bottom lead frame is similar to the foregoing structure but inverted. The bottom lead frame has a plurality of second leads 110. Each of the second leads 110 has a second inner lead 110A and a second outer lead 110B. Similarly, the thickness of the second inner leads 110A is smaller than the thickness of the second outer leads 110B so that a second accommodation space 130 is formed in the region of the second inner leads 110A. A second chip 112 is disposed in the second accommodation space 130 and located on the second inner leads 110A, which is also a Chip On Lead (COL) structure. The second chip 112 has a second active surface 112A and a second rear surface 128. The second chip 112 is attached to the second inner leads 110A with the second rear surface 112B, preferably by an insulating adhesive paste or an insulating tape (not shown). A plurality of contact points (not shown) are disposed on the second active surface 112A of the second chip 112 and are electrically coupled to the second leads 110 through the bonding wires 108 respectively, where the connection positions are preferably at the second inner leads 110A.

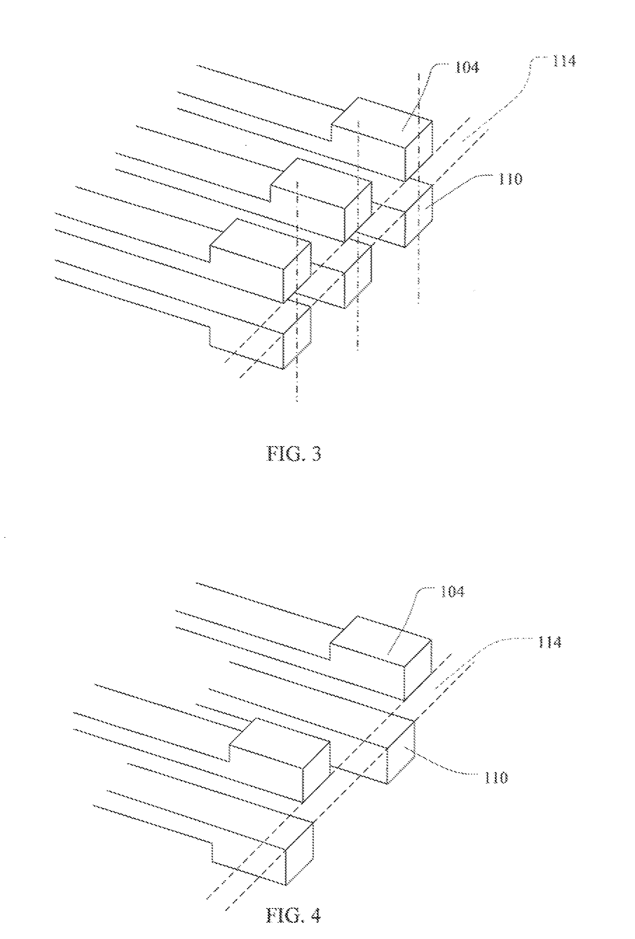

Please refer to FIG. 1, FIG. 3, and FIG. 4. FIG. 3 is a partially enlarged perspective view illustrating region A shown in FIG. 1 according to an embodiment of the present invention. FIG. 4 is a partially enlarged perspective view illustrating region A shown in FIG. 1 according to another embodiment of the present invention. The semifinished products of the foregoing two lead frames formed after die attachment and wire bonding are then attached to each other. Besides, if not considering the complexity of the process, the two lead frames can first be attached to each other, and the die attachment and the wire bonding processes are then conducted respectively for the two lead frames to form two bonded semifinished products. Since the chip packaging structure of the present invention can comprise the stack of two identical or two different chips, the two lead frames can have a variety of pin configurations. For example, the first chip 106 and the second chip 112 can both be the memory chips, and the contacts of the first chip 106 and the second chip 112 are arranged in a mirror image configuration; thus the pin configurations of the first leads 104 and the second leads 110 can correspond exactly to each other. As shown in FIG. 3, the first leads 104 and the second leads 110 correspond to each other and are connected to each other via an adhesion layer 114. Because the pin configurations of the first leads 104 and the second leads 110 correspond exactly to each other, the first leads 104 and the second leads 110 can be electrically isolated from each other via the adhesion layer 114 when the adhesion layer 114 is an electrically non-conductive adhesive. The first leads 104 and the second leads 110 can also be electrically coupled to each other via the adhesion layer 114 when the adhesion layer 114 is an electrically conductive adhesive such as an anisotropic conductive paste (ACP) or an anisotropic conductive film (ACF). The adhesion layer 114 can also comprise the electrically conductive adhesive and the electrically non-conductive adhesive simultaneously so that the attachment between the first leads 104 and the second leads 110 is partially electrically conducted and partially non-conducted.

In another embodiment of the present invention, the first chip 106 and the second chip 112 can be different kinds of chips. For example, the first chip 106 is a memory chip, while the second chip 112 is a logic chip. Therefore, a portion of the contacts of the first chip 106 requires independent input or output, and a portion of the contacts of the second chip 112 also requires independent input or output. As shown in FIG. 3, the first leads 104 and the second leads 110 can still correspond to each other and be connected to each other via the adhesion layer 114, where the adhesion layer 114 is the electrically non-conductive adhesive so that the first leads 104 and second leads 110 are electrically isolated from each other for independent input or output. In another aspect of the present invention, as shown in FIG. 4, a portion of the first leads 104 and a portion of the second leads 110 can be arranged in staggered manner so that whether the adhesion layer 114 is the electrically non-conductive adhesive or the electrically conductive adhesive, the first leads 104 and the second leads 110 can all be electrically isolated from each other through the staggered arrangement. It is worth mentioning that the corresponding arrangement and the staggered arrangement between the first leads 104 and the second leads 110, as shown in FIG. 3 and FIG. 4, can be applied in a chip packaging structure in combination according to the requirements. Therefore, in virtue of the electrical conductivity property of the adhesion layer, the attachment of the first leads 104 and the second leads 110 whether in corresponding arrangement or staggered arrangement can reach the condition that a portion of the first leads 104 and a portion of the second leads 110 are electrically coupled to each other, and the other portion of the first leads 104 and the other portion of the second leads 110 are electrically isolated from each other such that the circuit designs and the pin assignments in the chip packaging structure can be more flexible.

Next, an encapsulation process is conducted to cover the two lead frames with the chips which are attached to each other so that the encapsulating material 102 covers the first chip 106, the second chip 112, the bonding wires 108, the first inner leads 104A, the second inner leads 110A, part of the first outer leads 104B, and part of the second outer leads 110B and exposes a first surface 104C of the first outer leads 104B and a second surface 110C of the second outer leads 110B. The material of the encapsulating material 102 can be an epoxy resin or other suitable insulating material. The encapsulating material 102 has a top package surface 102A and a bottom package surface 102B opposite to the top package surface 102A. The first surface 104C of the first outer leads 104B is exposed on the top package surface 102A, and the second surface 110C of the second outer leads 110B is exposed on the bottom package surface 102B. The subsequent sawing/punching process of the lead frame or the packaging structure, the dejunk/deflash process, and the electroplating process of the leads are similar to the prior art, and hence are not discussed in detail herein.

The first surface 104C and the second surface 110C serve as the external contact points of the first leads 104 and the second leads 110 respectively so that the chip packaging structure 100 can further be stacked with other packaging structures or connected to other devices such as the circuit board. As described in the embodiment above, at some pin locations where the first leads 104 and the second leads 110 are electrically connected to each other by the adhesion layer 114, either the first surface 104C or the second surface 110C can be selected to serve as the external contact points. It is worth mentioning that some leads of a particular lead frame can be electrically unconnected to the chip located thereon in some embodiments. For example, one of the first leads 104 can be a dummy lead for the first chip 106, namely that it is not electrically coupled to the first chip 106 but is electrically coupled to one of the second leads 110 by the adhesion layer 114, so that the pin can connect to other packages and/or the circuit board(s) via the first surface 104C and the second surface 110C respectively. In other words, some contact point of the second chip 112 can be connected to external devices through the second lead 110 and/or the first lead 104, so that pin assignments can be more flexible.

Please refer to FIG. 2, which is a schematic cross sectional view illustrating a chip packaging structure according to another embodiment of the present invention. In some embodiments of the present invention, besides the foregoing COL structure the attachment mode between the chip and the lead frame can also be the Lead On Chip (LOC) type, where the chip contacts the lead frame with the active surface of the chip. In FIG. 2 the reference numerals the same as those of FIG. 1 denote the similar or the same elements, and hence are not discussed in detail herein, and only the differences compared with FIG. 1 are described. As shown in FIG. 2, the second chip 212 is located in the second accommodation space 130, and the second inner leads 110A are located on top of the second chip 212. The second chip 212 has a second active surface 212A and a second rear surface 212B. The second chip 212 is attached to the second inner leads 110A with the second active surface 212A, which is referred to as the Lead On Chip structure. Preferably, the second chip 212 is attached to the second inner leads 110A by an insulating adhesive paste or an insulating tape (not shown). A plurality of contacts (not shown) located near the center of the second active surface 212A of the second chip 212 are then electrically coupled to the second leads 110 through the bonding wires 108 respectively, where the connection positions are preferably at the second inner leads 110A. It is worth noting that in the embodiment the second accommodation space 130 can be reduced optionally, namely the thickness difference between the second inner leads 110A and the second outer leads 110B can be decreased so that the second rear surface 212B of the second chip 212 can be exposed on the bottom package surface 102B (not shown) after the encapsulation process. Hereby the thickness of the package can be reduced and the effect of heat dissipation of the second chip 212 can be enhanced.

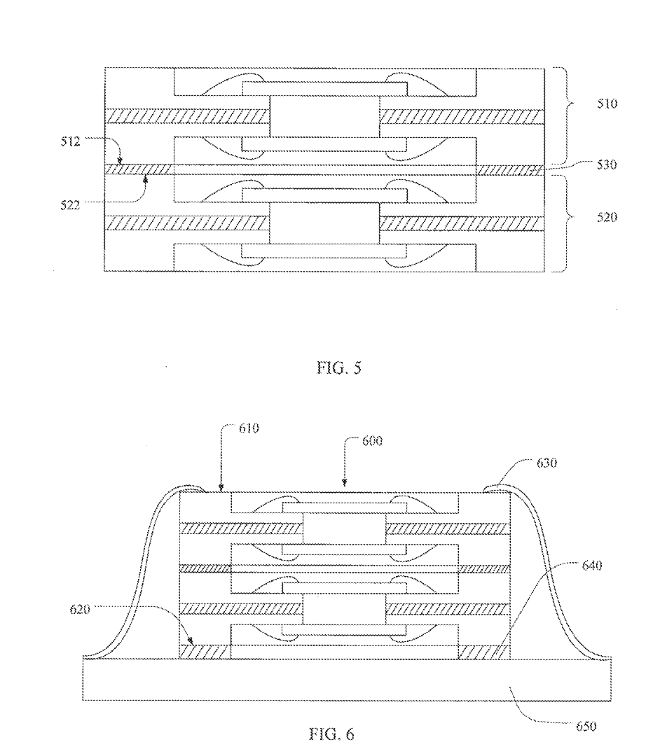

Please refer to FIG. 5, which is a schematic cross sectional view illustrating the chip packaging structures that stack on each other according to an embodiment of the present invention. The chip packaging structure either in FIG. 1 or FIG. 2 can form a package unit to be used in forming the stacked structure including two or more packages. For the detailed structure of each package unit, please refer to FIG. 1 or FIG. 2, and hence it is not discussed in detail herein. A package unit 510 and a package unit 520 can be stacked on each other, as shown in FIG. 5. An exposed surface 512 of the outer leads on the bottom of the package unit 510 (corresponding to the second surface 110C in FIG. 1) and an exposed surface 522 of the outer leads on the top of the package unit 520 (corresponding to the first surface 104C in FIG. 1) are connected to each other through an adhesion material 530 to form a stacked package structure. The adhesion material 530 can comprise an electrically conductive material and/or an electrically non-conductive material to have the package unit 510 and the package unit 520 electrically coupled to, electrically isolated from, or selectively electrically coupled to each other. In the embodiment, stacking of two package units is only taken as an example. Those skilled in the art should understand that a plurality of the package units can be stacked together according to the foregoing method.

Please refer to FIG. 6, which is a schematic cross sectional view illustrating the chip packaging structures that stack on each other and are disposed on a circuit board according to an embodiment of the present invention. Similarly, for the detailed structure of each package unit, please refer to FIG. 1 or FIG. 2, and hence it is not discussed in detail herein. The stacked package structure 600 after the chip packaging structures are stacked together, as shown in FIG. 5, can be disposed on a circuit board 650, such as a printed circuit board (PCB). As mentioned previously, the outer leads with the exposed surfaces on both the top package surface and the bottom package surface of the chip packaging structure in the present invention can all serve as the external contact points. On assembly, the exposed surface 620 (corresponding to the second surface 110C in FIG. 1) of the outer leads of the bottom package unit of the stacked package structure can be electrically coupled to the circuit board 650 by a solder material 640 with surface mount technology (SMT). The exposed surface 610 (corresponding to the first surface 104C in FIG. 1) of the outer leads of the top package unit of the stacked package structure can be electrically coupled to the circuit board 650 through a conductive element 630, such as a flexible printed circuit board.

To summarize the chip packaging structure of the present invention, two leadframe type semifinished products of Lead On Chip/Chip On Lead are stacked together to form a package unit which are favorable for the stacking of the packages. Moreover, in the invention the thickness of the inner leads is thinned to form a space for accommodating the chip so that the chip packaging structure can also be thinned. The chip packaging structure of the present invention uses the attachment of the lead frames to combine two identical or different chips in a package unit so as to benefit the stacking of the packages, wherein by using the electrically conductive adhesive and/or the electrically non-conductive adhesive to bond the outer leads of the two lead frames, the outer leads can then be selectively electrically coupled to or electrically isolated from each other for some particular pins according to the requirements, or can be selectively electrically coupled to the chips so that the circuit design and pin assignment of the chip packaging structure can be more flexible. Furthermore, for the chip packaging structure of the present invention, two lead frames are bonded to form a package unit with external contact points on both the top and bottom surfaces of the package unit so as to benefit the stacking of multiple package units. Therefore, the stacked package structure always has the external contact points on both the uppermost surface and the bottommost surface for additional connection to other devices such that the circuit design and pin assignment of the chip packaging structure are more flexible.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A chip packaging structure, comprising:
an encapsulating material, having a top package surface and a bottom package surface opposite to the top package surface;
a plurality of first leads, each of the first leads having a first inner lead and a first outer lead, the first leads disposed in the encapsulating material, a first surface of the first outer leads exposed on the top package surface;
a first chip, disposed in the encapsulating material, the first chip located on the first inner leads and electrically coupled to the first leads;
a plurality of second leads, each of the second leads having a second inner lead and a second outer lead, the second leads disposed in the encapsulating material, a second surface of the second outer leads exposed on the bottom package surface;
a second chip, disposed in the encapsulating material, the second chip located on the second inner leads and electrically coupled to the second leads; and
an adhesion layer, disposed in the encapsulating material and located between the first leads and the second leads so that the first leads and the second leads are connected to each other.

2. The chip packaging structure of claim 1, wherein the thickness of the first inner leads is smaller than the thickness of the first outer leads so that a first accommodation space is formed between the first inner leads and the top package surface, wherein the first chip is located in the first accommodation space.

3. The chip packaging structure of claim 1, wherein the thickness of the second inner leads is smaller than the thickness of the second outer leads so that a second accommodation space is formed between the second inner leads and the bottom package surface, wherein the second chip is located in the second accommodation space.

4. The chip packaging structure of claim 1, wherein the adhesion layer comprises an electrically non-conductive adhesive, the first leads are corresponding to the second leads respectively and are electrically isolated from the second leads by the electrically non-conductive adhesive.

5. The chip packaging structure of claim 1, wherein the adhesion layer comprises an electrically conductive adhesive, a portion of the first leads are corresponding to a portion of the second leads respectively and are electrically coupled to the portion of the second leads by the electrically conductive adhesive.

6. The chip packaging structure of claim 5, wherein the adhesion layer further comprises an electrically non-conductive adhesive, the other portion of the first leads are corresponding to the other portion of the second leads respectively and are electrically isolated from the other portion of the second leads by the electrically non-conductive adhesive.

7. The chip packaging structure of claim 5, wherein the other portion of the first leads and the other portion of the second leads are arranged in staggered manner to be electrically isolated from each other.

8. An electronic device, comprising:
a chip packaging structure, comprising:
an encapsulating material, having a top package surface and a bottom package surface opposite to the top package surface;
a plurality of first leads, each of the first leads having a first inner lead and a first outer lead, the first leads disposed in the encapsulating material, a first surface of the first outer leads exposed on the top package surface;
a first chip, disposed in the encapsulating material, the first chip located on the first inner leads and electrically coupled to the first leads;
a plurality of second leads, each of the second leads having a second inner lead and a second outer lead, the second leads disposed in the encapsulating material, a second surface of the second outer leads exposed on the bottom package surface;
a second chip, disposed in the encapsulating material, the second chip located on the second inner leads and electrically coupled to the second leads; and
an adhesion layer, disposed in the encapsulating material and located between the first leads and the second leads so that the first leads and the second leads are connected to each other; and
a circuit board, the chip packaging structure disposed on the circuit board and electrically coupled to the circuit board through the second surface of the second outer leads.

9. The electronic device of claim 8, further comprising a conductive element electrically coupling the first surface of the first outer leads to the circuit board.

10. The electronic device of claim 8, wherein the thickness of the first inner leads is smaller than the thickness of the first outer leads so that a first accommodation space is formed between the first inner leads and the top package surface, wherein the first chip is located in the first accommodation space.

11. The electronic device of claim 8, wherein the thickness of the second inner leads is smaller than the thickness of the second outer leads so that a second accommodation space is formed between the second inner leads and the bottom package surface, wherein the second chip is located in the second accommodation space.

12. The electronic device of claim 8, wherein the adhesion layer comprises an electrically non-conductive adhesive, the first leads are corresponding to the second leads respectively and are electrically isolated from the second leads by the electrically non-conductive adhesive.

13. The electronic device of claim 8, wherein the adhesion layer comprises an electrically conductive adhesive, a portion of the first leads are corresponding to a portion of the second leads respectively and are electrically coupled to the portion of the second leads by the electrically conductive adhesive.

14. The electronic device of claim 13, wherein the adhesion layer further comprises an electrically non-conductive adhesive, the other portion of the first leads are corresponding to the other portion of the second leads respectively and are electrically isolated from the other portion of the second leads by the electrically non-conductive adhesive.

15. The electronic device of claim 13, wherein the other portion of the first leads and the other portion of the second leads are arranged in staggered manner to be electrically isolated from each other.
